(19) United States
(12) Patent Application Publication
(10) Pub. No.: US 2001/0041467 A1
(43) Pub. Date: Nov. 15, 2001

(54) Terminal

(75) Inventors: Eiji Kikuchi, Tokyo (JP); Hiroji Yamakawa, Tokyo (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: NIPPON DICS CO., LTD., Tokyo (JP)

(21) Appl. No.: 09/795,441

(22) Filed: Mar. 1, 2001

(30) Foreign Application Priority Data
May 9, 2000 (JP) 2000-136273

(51) Int. Cl. H05K 1/00

(52) U.S. Cl. 439/82

(57) ABSTRACT

A terminal 1 is equipped with elastic legs 3a, 3b having ridges on the feet 19a, 19b thereof, and is equipped with two elastic arms 5a, 5b extending to either side of legs 3a, 3b at an angle somewhat less than perpendicular with respect thereto. Upon insertion of terminal 1 into terminal insertion hole 17 on board 9, legs 3a, 3b become constricted and the tips of arms 5a, 5b come in contact with wiring lands 15. Upon complete insertion of terminal 1 in board 9, elasticity causes the two constricted legs 3a, 3b to become splayed outward, the ridges of feet 19a, 19b catching on the rim of terminal insertion hole 17. Furthermore, the arms 5a, 5b, being bent upward, an elastic force therefrom acts so as to cause the ridges of legs 3a, 3b to press against board 9, securing terminal 1 tightly to board 9. Following complete insertion of terminal 1 in board 9, by squeezing together feet 19a, 19b of legs 3a, 3b and causing constriction of legs 3a, 3b, it is possible to cause the ridges of feet 19a, 19b to no longer catch on the rim of terminal insertion hole 17 as was described above, making it possible to remove terminal 1 from board 9.

### BACKGROUND

The present invention pertains to a terminal for attachment to a substrate, and more particularly pertains to an improvement in the mechanism whereby such terminal is attached to printed circuit board substrate. The terminal of the present invention is capable of being quickly and easily mounted to and removed from such substrate without causing damage to the substrate, the terminal, or to circuit components of which the terminal is a part.

Printed circuit boards are present in facsimile devices, mobile telephones, personal computers, and other such electrical and electronic equipment, and there are a wide variety of circuit components such as connectors, integrated circuit memories, and so forth attached to such printed circuit boards. To secure various circuit components to board substrate, terminals of the various circuit components must be soldered thereto.

In recent years, increased urgency has been felt in the need to switch over from a so-called disposable economy to a so-called recyclable economy so as to avoid problems such as depletion of natural resources and destruction of the natural environment on a global scale. It would appear likely sometime in the near future that the burden for further advances in recycling will be placed on the manufacturer, including that of products predicated upon separation of components such that the various electrical products which end up in the hands of consumers are recovered by the original manufacturers and are disassembled into a large number of components, and those components capable of being reused are incorporated into new products while those components incapable of be reused are discarded.

However, because conventional circuit component terminals are constructed so as to be attached and secured to board substrate by means of soldering, once such terminals are attached to board substrate it is in practice impossible to detach such circuit components from the board substrate without causing damage to both the printed circuit board and the circuit components.

Moreover, given the current level of the art, it is not possible to employ alloys of very high melting point as solder, since manufacture of circuit component terminals and printed circuit boards from highly heat resistant materials is difficult. For this reason, while quite aware of the harmful effects of lead on the environment, manufacturers are nonetheless forced to employ alloys of tin and lead, which are known to have comparatively low melting points, as solder. In addition, so long as solder is employed for attaching and securing circuit components to printed circuit boards, there will also be the problem that product must pass through various manufacturing steps which are indispensable to the soldering process but which are unfriendly to the environment, such as flux application, reflow treatment, solder dip, and cleaning.

### SUMMARY

The present invention pertains to a terminal for attachment to a substrate, and more particularly pertains to an improvement in the mechanism whereby such terminal is attached to printed circuit board substrate. The terminal of the present invention is capable of being quickly and easily mounted to and removed from such substrate without causing damage to the substrate, the terminal, or to circuit components of which the terminal is a part.

It is a goal of the present invention to provide a circuit component terminal capable of being mounted on board substrate with adequate strength of attachment without employment of soldering, and permitting easy and damage-free removal from printed circuit board.

A terminal according to the present invention is equipped with a leg that is inserted into a recess on a substrate, an engagement member provided on the leg so as to prevent detachment of the leg from the recess as a result of engagement of the engagement member with the recess when the leg is inserted into the recess, and an electrically conductive region that forms a closed circuit as a result of electrical connection with a wiring pattern on the substrate when the leg is at a prescribed location within the recess.

In accordance with the present invention, because a terminal leg is engaged at a prescribed location within a recess provided on a substrate, the terminal can be tightly secured to the substrate without employment of soldering. Furthermore, by releasing the engagement, a terminal secured to the substrate can be removed therefrom without causing damage to either the substrate or the terminal.

In a preferred mode for carrying out the invention, there is further provided a terminal locking member that causes the substrate to come in compressive contact with the engagement member, locking the terminal to the substrate, when the engagement member of the leg engages with the recess. The terminal locking member accomplishes this compressive contact by means of an elastic restoring force acting in a direction opposite to the direction of insertion of the leg.

In a preferred mode for carrying out the invention, the recess is a through-hole.

In a preferred mode for carrying out the invention, there are a plurality of legs which branch off from the terminal body, the plurality of legs being constructed so as to permit elastic deformation such that an elastic restoring force acts so as to increase the size of a gap between respective legs.

In a preferred mode for carrying out the invention, the terminal is constructed so as to permit elastic deformation such that an elastic restoring force acts in a direction tending to press the leg against a wall surface of the recess.

### BRIEF DESCRIPTION OF DRAWINGS

These and other features, aspects, and advantages of the present invention will become better understood with reference to the following description, appended claims, and accompanying drawings where:

FIG. 1 is an oblique view showing the front of a terminal associated with a first embodiment of the present invention,

FIG. 2 is a view as seen from section A-A in FIG. 1 showing a stage in the sequence of operations during mounting of a terminal associated with the first embodiment on a board,

FIG. 3 is a view as seen from section A-A in FIG. 1 showing a stage in the sequence of operations during mounting of a terminal associated with the first embodiment on a board,

FIG. 4 is a view as seen from section A-A in FIG. 1 showing a stage in the sequence of operations during mounting of a terminal associated with the first embodiment on a board,

FIG. 5 is an oblique view of an electrical connector wherein use of a terminal associated with the first embodiment has been applied,

FIG. 6 is an oblique view including a broken-out vertical section and showing the situation existing when the electrical connector of FIG. 5 has been completely inserted (mounted) in a board,

FIG. 7 is an oblique view showing the situation existing when a mating connector is mated with the electrical connector of FIG. 5,

FIG. 8 is an oblique view of a stacked-board connector wherein use of a terminal associated with a first variation on the first embodiment of the present invention has been applied,

FIG. 9 is an oblique view including a broken-out vertical section and showing the situation existing when the stacked-board connector of FIG. 8 has been mounted on a board,

FIG. 10 is an oblique view showing the situation existing when boards are stacked using the stacked-board connector of FIG. 8,

FIG. 11 is an oblique view of a female-type connector wherein use of a terminal associated with a second variation on the first embodiment of the present invention has been applied,

FIG. 12 is an oblique view including a broken-out vertical section and showing the situation existing when the female-type connector of FIG. 11 has been completely mounted on a board,

FIG. 13 is an oblique view of a male-type connector wherein use of a terminal associated with a third variation on the first embodiment of the present invention has been applied,

FIG. 14 is an oblique view including a broken-out vertical section and showing the situation existing when the male-type connector of FIG. 13 has been completely mounted on a board,

FIG. 15 is an oblique view showing the situation existing when the male-type connector of FIG. 13 is engaged with the female-type connector of FIG. 11,

FIG. 16 is a vertical sectional view showing the situation existing when the male-type connector of FIG. 13 is engaged with the female-type connector of FIG. 11,

FIG. 17 is an oblique view showing boards stacked using the male-type connector of FIG. 13 engaged with the female-type connector of FIG. 11,

FIG. 18 is an oblique view of a terminal associated with a second embodiment of the present invention,

FIG. 19 is a side view showing the shape of a terminal associated with the second embodiment prior to mounting of that terminal on a board,

FIG. 20 is a side view showing change in the shape of a terminal associated with the second embodiment during mounting of that terminal on a board,

FIG. 21 is a side view showing change in the shape of a terminal associated with the second embodiment during mounting of that terminal on a board,

FIG. 22 is an oblique view of an electrical connector wherein use of a terminal associated with the second embodiment has been applied,

FIG. 23 is an oblique view including a broken-out vertical section and showing the situation existing when the electrical connector of FIG. 22 has been mounted on a board,

FIG. 24 is an oblique view showing the situation existing when a mating connector is mated with the electrical connector of FIG. 22,

FIG. 25 is an oblique view of a stacked-board connector wherein use of a terminal associated with a first variation on the second embodiment of the present invention has been applied,

FIG. 26 is an oblique view including a broken-out vertical section and showing the situation existing when the stacked-board connector of FIG. 25 has been mounted on a board,

FIG. 27 is an oblique view showing the situation existing when boards are stacked using the stacked-board connector of FIG. 25,

FIG. 28 is an oblique view of a female-type connector wherein use of a terminal associated with a second variation on the second embodiment of the present invention has been applied,

FIG. 29 is an oblique view including a broken-out vertical section and showing the situation existing when the female-type connector of FIG. 28 has been mounted on a board,

FIG. 30 is an oblique view of a male-type connector wherein use of a terminal associated with a third variation on the second embodiment of the present invention has been applied,

FIG. 31 is an oblique view including a broken-out vertical section and showing the situation existing when the male-type connector of FIG. 30 has been mounted on a board,

FIG. 32 is an oblique view showing the situation existing when the male-type connector of FIG. 30 is engaged with the female-type connector of FIG. 28,

FIG. 33 is a vertical sectional view showing the situation existing when the male-type connector of FIG. 30 is engaged with the female-type connector of FIG. 28, and

FIG. 34 is an oblique view showing boards stacked using the male-type connector of FIG. 30 engaged with the female-type connector of FIG. 28.

### DESCRIPTION

The present invention pertains to a terminal for attachment to a substrate, and more particularly pertains to an improvement in the mechanism whereby such terminal is attached to printed circuit board substrate. The terminal of the present invention is capable of being quickly and easily mounted to and removed from such substrate without causing damage to the substrate, the terminal, or to circuit components of which the terminal is a part.

Below, embodiments of the present invention are described in detail with reference to the drawings.

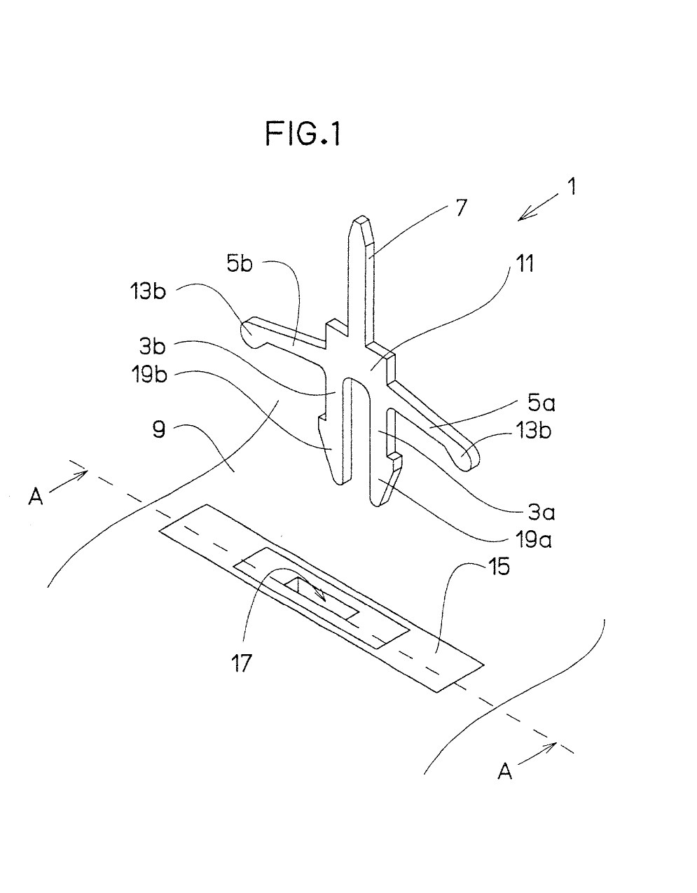

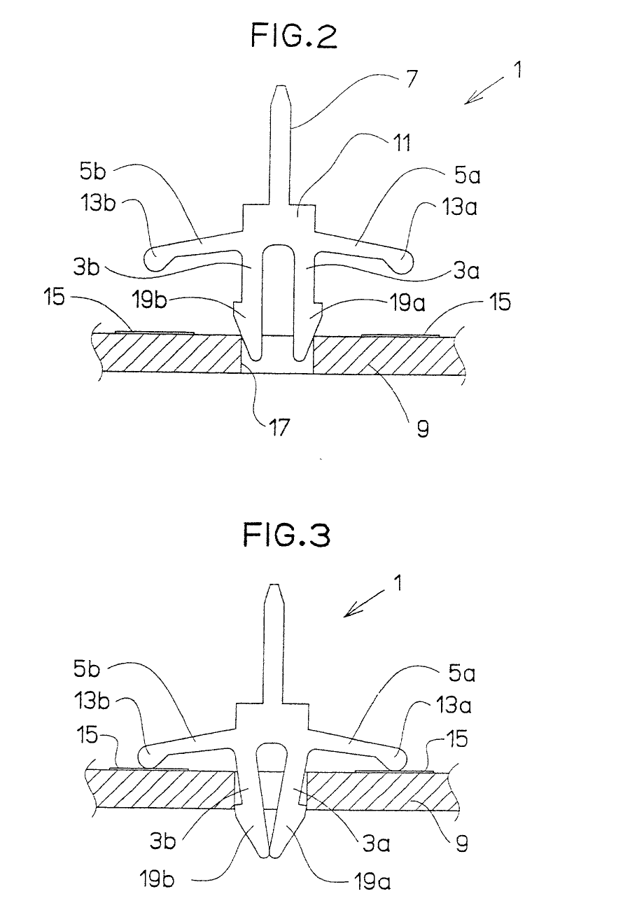

FIG. 1 is an oblique view of a terminal associated with a first embodiment of the present invention, and FIGS. 2 through 4 are front views showing changes in the shape of the terminal associated with the present embodiment during mounting of that terminal on a printed circuit board. Moreover, at reference symbol 9 in FIGS. 2 through 4, section A-A of printed circuit board (hereinafter “board”) 9 in FIG. 1 is shown.

Referring first to FIG. 1, a terminal 1 associated with the present embodiment has two legs 3a, 3b; two arms 5a, 5b; a neck 7; and a terminal body 11 which joins these elements together.

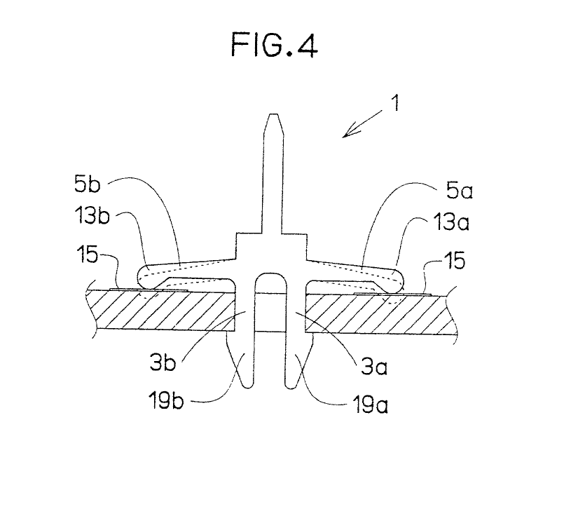

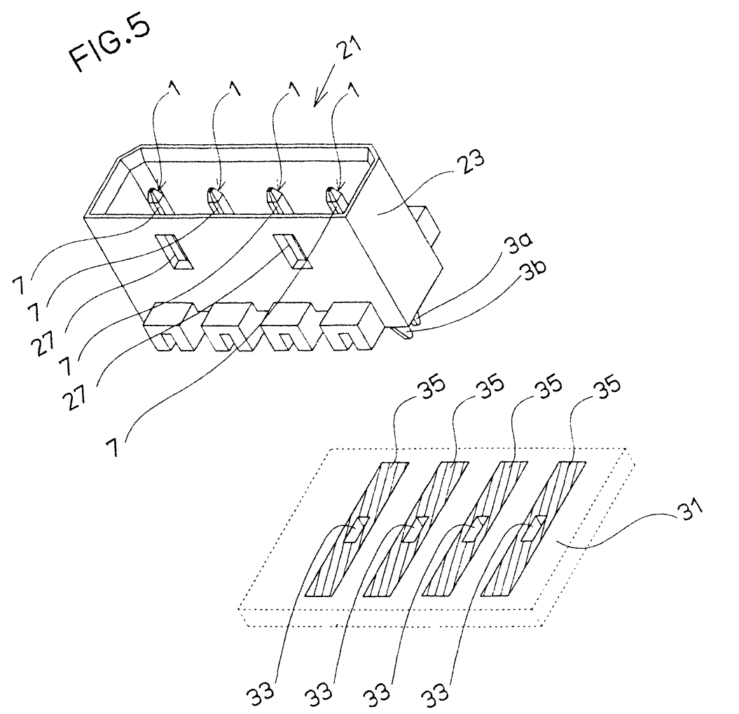

As shown at FIG. 2, the two legs 3a, 3b, which are mutually parallel and extend downward from the terminal body 11, are for insertion into a terminal insertion hole 17 provided at board 9. The two legs 3a, 3b respectively possess, at the tips thereof, feet 19a, 19b, which are pointed after the fashion of arrowheads, the width of each foot 19a, 19b narrowing inwardly as one proceeds from the base to the tip thereof. As shown in FIGS. 3 and 4, at the base of each foot 19a, 19b is a ridge that can be caught by the rim of terminal insertion hole 17 when terminal 1 is inserted completely in board 9, preventing detachment of terminal 1. As shown in FIGS. 2 and 3, terminal 1 is formed such that the distance from the outer edge of the ridge of left foot 19b to the outer edge of the ridge of right foot 19a when the legs 3a, 3b are in their relaxed (unsprung) state is somewhat larger than the width of terminal insertion hole 17.

Referring to FIG. 3, legs 3a, 3b possess elasticity, and the above-described shape of feet 19a, 19b encourages constriction upon insertion thereof into terminal insertion hole 17 (i.e., the previously opened legs 3a, 3b move inward toward a closed arrangement). In addition, referring now to FIG. 4, upon being completely inserted (i.e., mounted) therein, elasticity (restorative spring force) causes the two constricted legs 3a, 3b to become splayed outward (i.e., the previously closed legs 3a, 3b move outward toward an open arrangement), the respective ridges of feet 19a, 19b catching on the rim of terminal insertion hole 17, preventing detachment of terminal 1. Moreover, following complete insertion (i.e., mounting) of terminal 1 in board 9, by squeezing together feet 19a, 19b of legs 3a, 3b and causing constriction of legs 3a, 3b, it is possible to cause the ridges of feet 19a, 19b to no longer catch on the rim of terminal insertion hole 17 as was described above, making it possible to remove terminal 1 from board 9. Restating this in more detail, upon constriction of legs 3a, 3b, elasticity (restorative spring force) of arms 5a, 5b, described below, causes feet 19a, 19b, the ridges of which have been disengaged from the rim of terminal insertion hole 17, to enter terminal insertion hole 17, permitting removal of terminal 1 from board 9. Terminal 1 associated with the present embodiment is thus capable of being easily removed from board 9 without causing damage to board 9, terminal 1, or to circuit components of which terminal 1 is a part.

Referring to FIG. 2, the two arms 5a, 5b possess elasticity and when in their relaxed (unsprung) state are spread out to either side of legs 3a, 3b at an angle somewhat less than perpendicular with respect thereto (put another way, arms 5a, 5b extend from terminal body 11 in directions angled somewhat downward relative to the horizontal). Provided at the tips of arms 5a, 5b are fingers 13a, 13b which come in contact with wiring lands 15 (a land being a patterned wiring element arranged on board 9 and in electrical contact with electrical circuit components or electronic circuit components on board 9) on the surface of board 9 when terminal 1 is inserted in board 9. Fingers 13a, 13b are more or less round in shape so as to satisfactorily slide along the surface of board 9 (over wiring lands 15) when terminal 1 is mounted on board 9.

Referring to FIG. 3, upon insertion of terminal 1 into terminal insertion hole 17 of board 9, fingers 13a, 13b of the two arms 5a, 5b come in contact with wiring lands 15 on the surface of board 9. In addition, referring now to FIG. 4, upon complete insertion (mounting) of terminal 1 in board 9, the two arms 5a, 5b are bent and raised from the relaxed (unsprung) position indicated by a broken line in the drawing to the bent (sprung) position indicated by a solid line in the drawing, the fingers 13a, 13b at the tips thereof sliding over wiring lands 15. At this time, elasticity (restorative spring force) of arms 5a, 5b causes terminal 1 to rise as if to exit therefrom, but the ridges on legs 3a, 3b catch on the rim of terminal insertion hole 17, thus preventing terminal 1 from rising further and becoming detached from board 9. In other words, arms 5a, 5b, by virtue of an elastic force therefrom, cause the ridges of legs 3a, 3b to press against board 9, securing terminal 1 tightly to board 9. This permits terminal 1 to be tightly secured to board 9 without use of soldering.

Referring back to FIG. 2, neck 7 extends from terminal body 11 in a direction opposite to that of legs 3a, 3b. Neck 7 may serve as an electric lead connecting member, for example when terminal 1 is used in an electrical connector, described in further detail below, in which case neck 7 might extend in pin-like fashion from the interior of the housing of such connector so as to permit electrical connection with an electric lead of a mating connector which is mated with the connector.

The foregoing construction of terminal 1 allows it to be mounted to and removed from board 9 much more easily and in a much shorter time than was the case conventionally (i.e., inasmuch as it is designed to be removable). Such a terminal 1 may be applied to use in printed circuit boards present in comparatively small-size electrical and electronic equipment such as mobile telephones and portable organizer-type devices which may have voice and data capabilities and be capable of connection with various types of networks, not to mention use in printed circuit boards present in comparatively large-size electrical and electronic equipment such as facsimile devices and personal computers. Specifically, terminal 1 may for example be applied to use as a terminal in any number of the various types of connectors found on printed circuit boards.

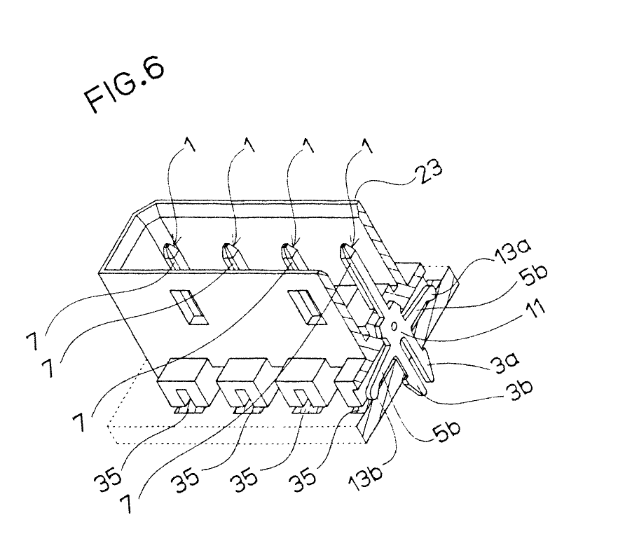

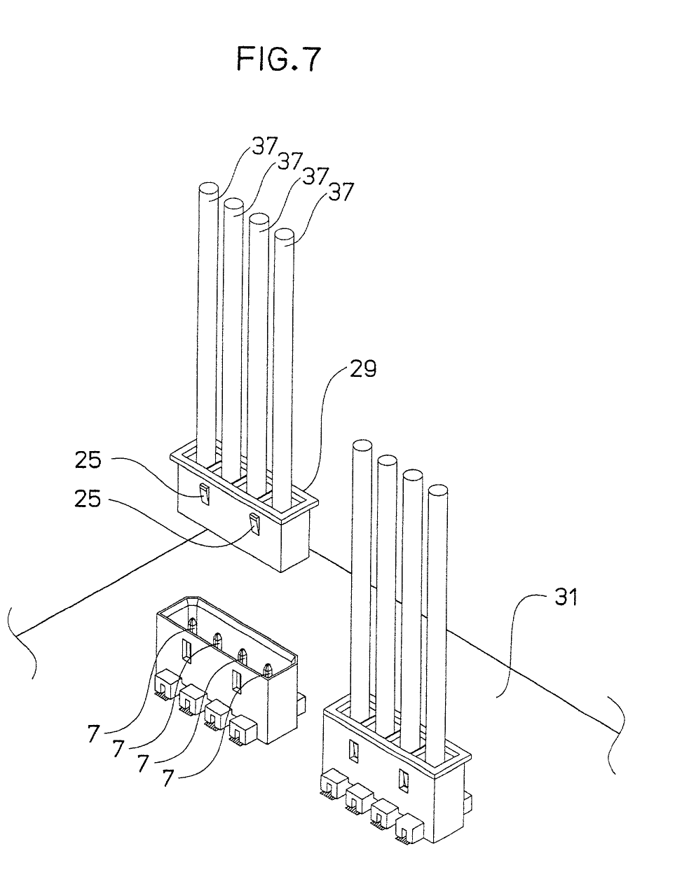

FIG. 5 is an oblique view of an electrical connector wherein use of terminal 1 has been applied. FIG. 6 is an oblique view including a broken-out vertical section and showing the situation existing when the electrical connector of FIG. 5 has been completely inserted (mounted) in a board. FIG. 7 is an oblique view showing the situation existing when a mating connector is mated with the electrical connector of FIG. 5.

Referring first to FIG. 5, electrical connector 21 has one or more (for example, four) terminals 1, 1, . . . within a housing 23. Housing 23 is formed such that on a prescribed side thereof there are slots 27, 27 for engagement with tabs 25, 25 of mating connector 29 shown in FIG. 7, respective terminals 1, 1, . . . being disposed in fixed-pitch fashion at the interior thereof. Referring now to FIG. 6, housing 23 is such that the terminal bodies 11, 11, . . . (a reference numeral being shown for only one such element in the drawing) of respective terminals 1, 1, . . . are captured within the basal interior of housing 23 so as to secure respective terminals 1, 1, . . . therein. Extending upwardly from the basal interior surface of housing 23 are necks 7, 7, . . . of respective terminals 1, 1, . . . ; projecting downwardly from the basal exterior surface of housing 23 are legs (3a, 3b), (3a, 3b), . . . (only one such element being shown in the drawing) of respective terminals 1, 1, . . . ; and fingers (13a, 13b), (13a, 13b), . . . of arms (5a, 5b), (5a, 5b), . . . (only one such element being shown in the drawing) extend downwardly so as to come in contact with wiring lands 35, 35, . . . When mating connector 29 shown in FIG. 7 is mated with this electrical connector 21, necks 7, 7, . . . of respective terminals 1, 1, . . . serve as electric lead connecting members for electrical connection to electric leads 37, 37, of mating connector 29.

Returning to FIG. 5, when this electrical connector 21 is installed on a board 31, legs (3a, 3b), (3a, 3b), . . . of respective terminals 1, 1, . . . are inserted within terminal insertion holes 33, 33, . . . in board 31. As a result, while not shown in the drawing, respective legs (3a, 3b), (3a, 3b), . . . of respective terminals 1, 1, . . . are constricted and enter terminal insertion holes 33, 33, . . . , and fingers (13a, 13b), (13a, 13b), . . . of arms (5a, 5b), (5a, 5b), . . . come in contact with wiring lands 35, 35, . . . In addition, referring now to FIG. 6, upon complete insertion of electrical connector 21 into board 31, the constricted legs (3a, 3b), (3a, 3b), . . . spread apart due to elastic forces therefrom, and the ridges (reference numeral not shown) of the feet thereof catch on the rims of terminal insertion holes 33, 33, . . . Furthermore, the positions of respective arms (5a, 5b), (5a, 5b), . . . are bent upward from their relaxed (unsprung) positions, the fingers (13a, 13b), (13a, 13b), . . . of respective arms (5a, 5b), (5a, 5b), . . . sliding over wiring lands 35, 35, . . . As a result, respective arms (5a, 5b), (5a, 5b), . . . , by virtue of elastic forces therefrom, cause the ridges of respective legs (3a, 3b), (3a, 3b), . . . to press against board 31, securing electrical connector 21 tightly to board 31. Such a constitution permits electrical connector 21 to be tightly secured to board 31 without use of soldering. Moreover, following complete insertion of electrical connector 21, by squeezing together the feet of respective legs (3a, 3b), (3a, 3b), . . . and causing constriction of the respective legs (3a, 3b), (3a, 3b), . . . , it is possible to cause the ridges to no longer catch on the rims of terminal insertion holes 33, 33, . . . as was described above, making it possible to remove electrical connector 21 from board 31. That is, electrical connector 21 associated with the present embodiment is capable of being easily removed from board 31 without causing damage to board 31 or electrical connector 21. Moreover, such an electrical connector 21 is capable of being mounted to and removed from board 31 much more easily and in a much shorter time than was the case conventionally (i.e., inasmuch as it is designed to be removable).

Referring to FIG. 7, a mating connector 29 such as that shown in the drawing may be mated with this electrical connector 21. One or more (for example, four) electric leads 37, 37, . . . are attached to mating connector 29, and mating connector 29 is provided with four terminal holes, not shown, at a side facing electrical connector 21, and is provided with tabs 25, 25 on a prescribed side thereof. Upon insertion of this mating connector 29 into electrical connector 21, necks 7, 7, . . . of terminals 1, 1, . . . of electrical connector 21 enter the terminal holes on mating connector 29. Upon complete insertion of mating connector 29 into electrical connector 21, tabs 25, 25 of mating connector 29 engage with slots 27, 27 on housing 23 of electrical connector 21, preventing detachment of mating connector 29 therefrom, and the respective terminals 1, 1, . . . are electrically connected to electric leads 37, 37, . . . Furthermore, mating connector 29 is such that depression of tabs 25, 25 makes it possible for mating connector 29 to be pulled away and detached from electrical connector 21.

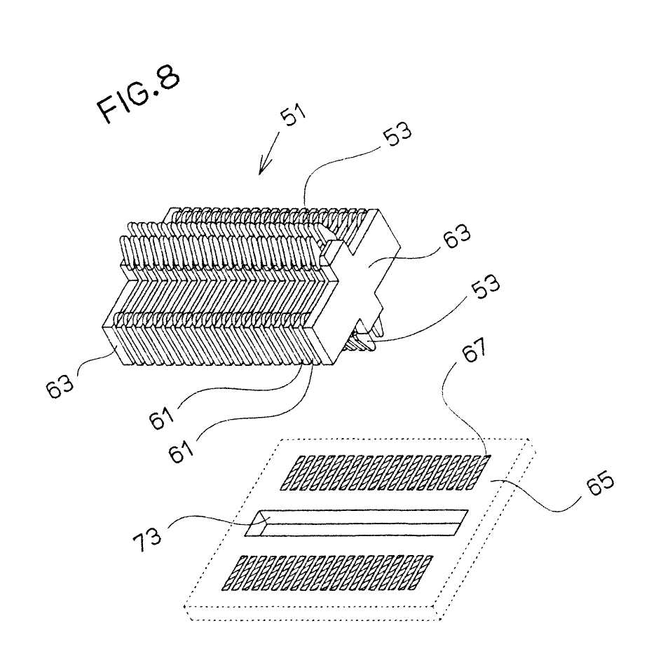

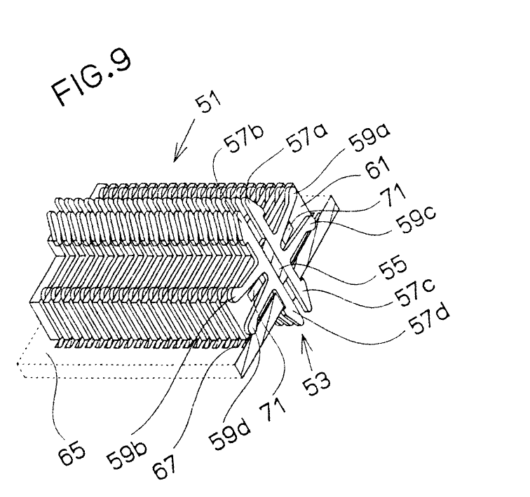

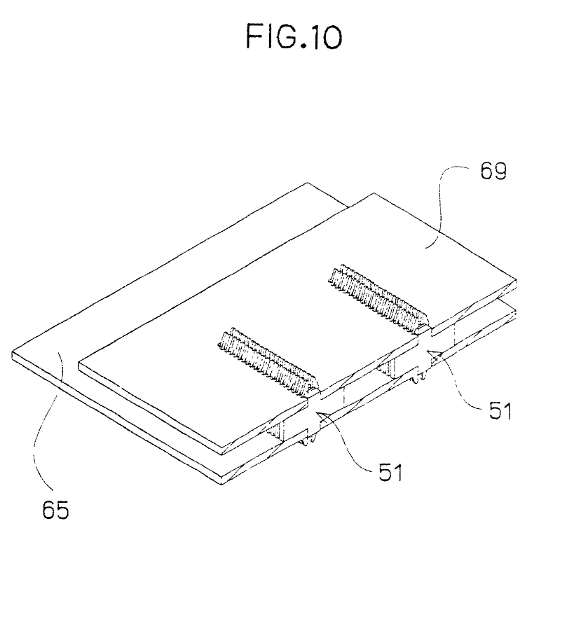

FIG. 8 is an oblique view of a stacked-board connector wherein use of a terminal associated with a first variation on the first embodiment of the present invention has been applied. FIG. 9 is an oblique view including a broken-out vertical section and showing the situation existing when the stacked-board connector of FIG. 8 has been mounted on a board. FIG. 10 is an oblique view showing the situation existing when boards are stacked using the stacked-board connector of FIG. 8.

Referring first to FIG. 9, a terminal 53 associated with a first variation on the first embodiment of the present invention has a vertically symmetric shape and a more or less centrally located body 55. Body 55 has mutually parallel legs 57a, 57b extending upwardly from body 55, and has mutually parallel legs 57c, 57d extending downwardly from body 55. Furthermore, body 55 has arms 59a, 59b which are spread out to either side of legs 57a, 57b at an angle somewhat less than perpendicular with respect thereto (put another way, arms 59a, 59b extend from body 55 in directions angled somewhat upward relative to the horizontal), and has arms 59c, 59d which are spread out to either side of legs 57c, 57d at an angle somewhat less than perpendicular with respect thereto (put another way, arms 59c, 59d extend from body 55 in directions angled somewhat downward relative to the horizontal). The structures and functions of respective legs 57a through 57d and respective arms 59a through 59d are similar to those of legs 3a, 3b and arms 5a, 5b of terminal 1, described above.

With continued reference to FIG. 9, in constructing a stacked-board connector 51, to be described below, this terminal 53 is secured to a terminal securing plate 61. Terminal securing plate 61 has two engagement tabs 71, 71, terminal 53 being secured thereto as a result of engagement of engagement tabs 71, 71 by the wedge-shaped region between arms 59a, 59c on the right side of terminal 53, and by the wedge-shaped region between arms 59b, 59d on the left side of terminal 53.

Referring to FIGS. 8 and 9, stacked-board connector 51 is constructed in layered fashion from multiple sets of terminals 53 and terminal securing plates 61, and is equipped, at either outer end thereof, with cover plates 63, 63 covering this stacked-board connector 51. With continued reference to FIGS. 8 and 9, legs (57a-57d), (57a-57d), . . . and fingers (reference numerals not shown) of arms (59a-59d), (59a-59d), . . . of respective terminals 53, 53, . . . extend above and below the profile of terminal securing plates 61, 61, . . .

With continued reference to FIGS. 8 and 9, when this stacked-board connector 51 is mounted on a board 65, the lower legs (57c, 57d), (57c, 57d), . . . of respective terminals 53, 53, . . . are inserted into a prescribed connector insertion hole 73 on board 65. Upon so doing, respective lower legs (57c, 57d), (57c, 57d), . . . are constricted and enter insertion hole 73 by virtue of elasticity and the shape of the tips of lower legs (57c, 57d), (57c, 57d), . . . , and the fingers of respective lower arms (59c, 59d), (59c, 59d), . . . come in contact with wiring lands 67 on board 65. When stacked-board connector 51 is completely inserted into board 65, respective constricted lower legs (57c, 57d), (57c, 57d), . . . spread apart due to elastic forces therefrom, and the ridges of the feet thereof catch on the rim of insertion hole 73. Furthermore, respective lower arms (59c, 59d), (59c, 59d), . . . being bent upward, elastic forces therefrom act such that the respective lower arms (59c, 59d), (59c, 59d), . . . cause the ridges of lower legs (57c, 57d), (57c, 57d), . . . to press against board 65, securing stacked-board connector 51 tightly to board 65. Referring to FIG. 10, the upper legs (57a, 57b), (57a, 57b), . . . of respective terminals 53, 53, . . . of stacked-board connector 51 are inserted in like fashion into a prescribed connector insertion hole (not shown) on board 69, mounting stacked-board connector 51 onto board 69. By so doing, it is possible, through use of stacked-board connector 51, for two boards 65, 69 to be stacked in multiple (mutually parallel) layers, as shown in FIG. 10, and for those boards 65, 69 to be electrically connected.

Moreover, by thereafter squeezing together the feet of respective lower legs (57c, 57d), (57c, 57d), . . . of respective terminals 53, 53, . . . and causing constriction of the respective lower legs (57c, 57d), (57c, 57d), . . . , it is possible to cause the ridges of respective lower legs (57c, 57d), (57c, 57d), . . . to no longer catch on the rim of insertion hole 73 as was described above, making it possible to remove stacked-board connector 51 from board 65 (and stacked-board connector 51 may be removed in like fashion from board 69). That is, stacked-board connector 51 is capable of being mounted to and removed from board 65 (or board 69) easily and in a short time (i.e., inasmuch as it is designed to be removable).

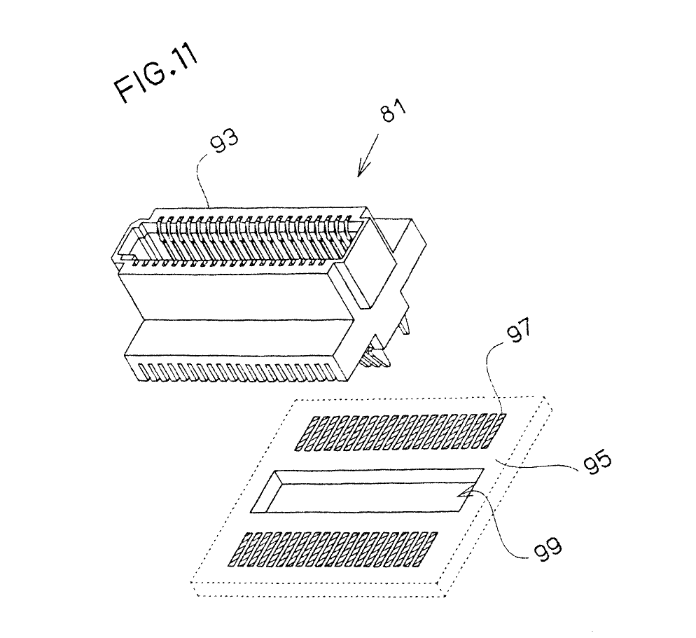

FIG. 11 is an oblique view of a female-type connector wherein use of a terminal associated with a second variation on the first embodiment of the present invention has been applied. FIG. 12 is an oblique view including a broken-out vertical section and showing the situation existing when the female-type connector of FIG. 11 has been completely mounted on a board.

Referring first to FIG. 12, a terminal 83 associated with a second variation on the first embodiment of the present invention has a leg 85 which extends in a downward direction, a neck 87 extending upwardly from leg 85, and an arm 89 extending from leg 85 at an angle somewhat less than perpendicular with respect thereto. The structures and functions of leg 85 and arm 89 are similar to those of legs 3a, 3b and arms 5a, 5b of terminal 1, described above. The shape of neck 87 is such that the tip thereof widens in barb-like fashion in a direction opposite that of the direction of extension of arm 89, permitting a male-type connector, described below, to be guided into female-type connector 81. Neck 87 is such as to permit contact with a terminal of a male-type connector, described below, when the male-type connector engages with female-type connector 81.

With continued reference to FIG. 12, female-type connector 81 has a housing 93 possessing space for engagement of a male-type connector, paired terminals 83, 83 being arrayed within housing 93 in fixed-pitch fashion along a direction orthogonal to the vertical section of the drawing. Paired terminals 83, 83 are arranged in horizontally symmetric fashion so as to straddle housing base 91. At paired terminals 83, 83, the tips of necks 87, 87 extend somewhat beyond the interior side surface of housing 93; legs 85, 85 protrude from the surface of contact between housing 93 and board 95; and the fingers of arms 89, 89 are such that when in their relaxed (unsprung) state, before mounting of female-type connector 81 on board 95, they extend somewhat beyond the plane corresponding to the surface of contact between housing 93 and board 95.

Action of this female-type connector 81 during mounting thereof on board 95 is more or less identical to that of the above-described stacked-board connector 51 during mounting thereof on a board. That is, with reference to FIGS. 11 and 12, upon insertion of legs (85, 85), (85, 85), . . . of paired terminals (83, 83), (83, 83), . . . into a prescribed connector insertion hole 99 on board 95, respective legs (85, 85), (85, 85), . . . are constricted and enter insertion hole 99 by virtue of elasticity and the shape of respective legs (85, 85), (85, 85), . . . , and the fingers of respective arms (89, 89), (89, 89), . . . come in contact with wiring lands 97 on board 95. When female-type connector 81 is completely inserted into board 95, respective constricted legs (85, 85), (85, 85), . . . spread apart due to respective elastic forces therefrom, and the ridges of the respective feet thereof catch on the rim of insertion hole 99, as shown in FIG. 12. Furthermore, respective arms (89, 89), (89, 89), . . . being bent upward, respective elastic forces therefrom act so as to cause the ridges of legs (85, 85), (85, 85), . . . to press against board 95, securing female-type connector 81 tightly to board 95. Moreover, by thereafter squeezing together the feet of respective legs (85, 85), (85, 85), . . . and causing constriction of respective legs (85, 85), (85, 85), . . . , it is possible to cause the ridges of respective legs (85, 85), (85, 85), . . . to no longer catch on the rim of insertion hole 99 as was described above, making it possible to remove female-type connector 81 from board 95.

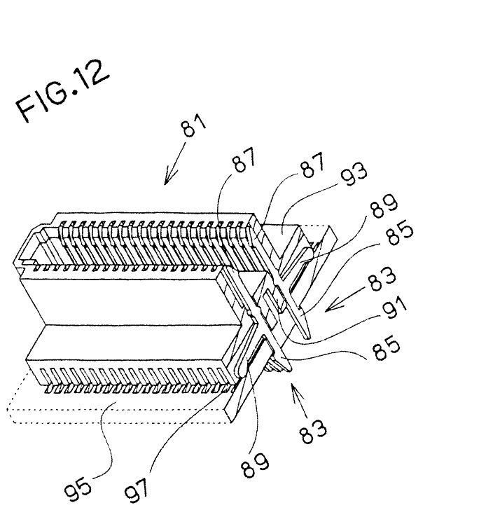

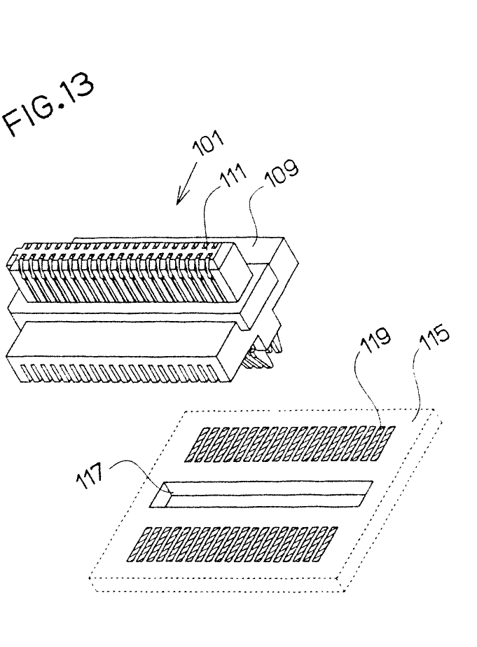

FIG. 13 is an oblique view of a male-type connector wherein use of a terminal associated with a third variation on the first embodiment of the present invention has been applied. FIG. 14 is an oblique view including a broken-out vertical section and showing the situation existing when the male-type connector of FIG. 13 has been completely mounted on a board.

Referring first to FIG. 14, the shape of a terminal 103 associated with a third variation on the first embodiment of the present invention is more or less identical to that of the above-described terminal 83 of female-type connector 81, the only exception being that the shape of neck 105 is somewhat different. To wit, the shape of neck 105 of terminal 103 is such that the tip thereof widens in barb-like fashion in the direction of extension of arm 107, permitting male-type connector 101 to be guided into a female-type connector 81. With additional momentary reference to FIG. 12, neck 105 is such that it comes in contact with neck 87 of terminal 83 of female-type connector 81 when male-type connector 101 engages with female-type connector 81.

Referring again to FIG. 14, male-type connector 101 has a housing 109 possessing a convex cross-section so as to permit engagement with female-type connector 81, paired terminals 103, 103 being arrayed more or less centrally on housing 109 in fixed-pitch fashion along a direction orthogonal to the vertical section of the drawing. Paired terminals 103, 103 are arranged in horizontally symmetric fashion so as to straddle wall 111 which is located more or less centrally on housing 109. At paired terminals 103, 103, the tips of necks 105, 105 extend somewhat beyond either wall surface of wall 111; legs 113, 113 protrude from the surface of contact between housing 109 and board 115; and the fingers of arms 107, 107 are such that when in their relaxed (unsprung) state, before mounting of male-type connector 101 on board 115, they extend somewhat beyond the plane corresponding to the surface of contact between housing 109 and board 115.

Action of this male-type connector 101 during mounting thereof on board 115 is more or less identical to that of the above-described female-type connector 81 during mounting thereof on a board. That is, with reference to FIGS. 13 and 14, upon insertion of legs (113, 113), (113, 113), . . . of paired terminals (103, 103), (103, 103), into a prescribed connector insertion hole 117 on board 115, respective legs (113, 113), (113, 113), . . . are constricted and enter insertion hole 117 by virtue of elasticity and the shape of legs (113, 113), (113, 113), . . . , and the fingers of respective arms (107, 107), (107, 107), . . . come in contact with wiring lands 119 on board 115. When male-type connector 101 is completely inserted into board 115, respective constricted legs (113, 113), (113, 113), . . . spread apart due to respective elastic forces therefrom, and the ridges of the respective feet thereof catch on the rim of insertion hole 117, as shown in FIG. 14. Furthermore, respective arms (107, 107), (107, 107), . . . being bent upward, respective elastic forces therefrom act so as to cause the ridges of legs (113, 113), (113, 113), . . . to press against board 115, securing male-type connector 101 tightly to board 115. Moreover, by thereafter squeezing together the feet of respective legs (113, 113), (113, 113), . . . and causing constriction of respective legs (113, 113), (113, 113), . . . , it is possible to cause the ridges of respective legs (113, 113), (113, 113), . . . to no longer catch on the rim of insertion hole 117 as was described above, making it possible to remove male-type connector 101 from board 115.

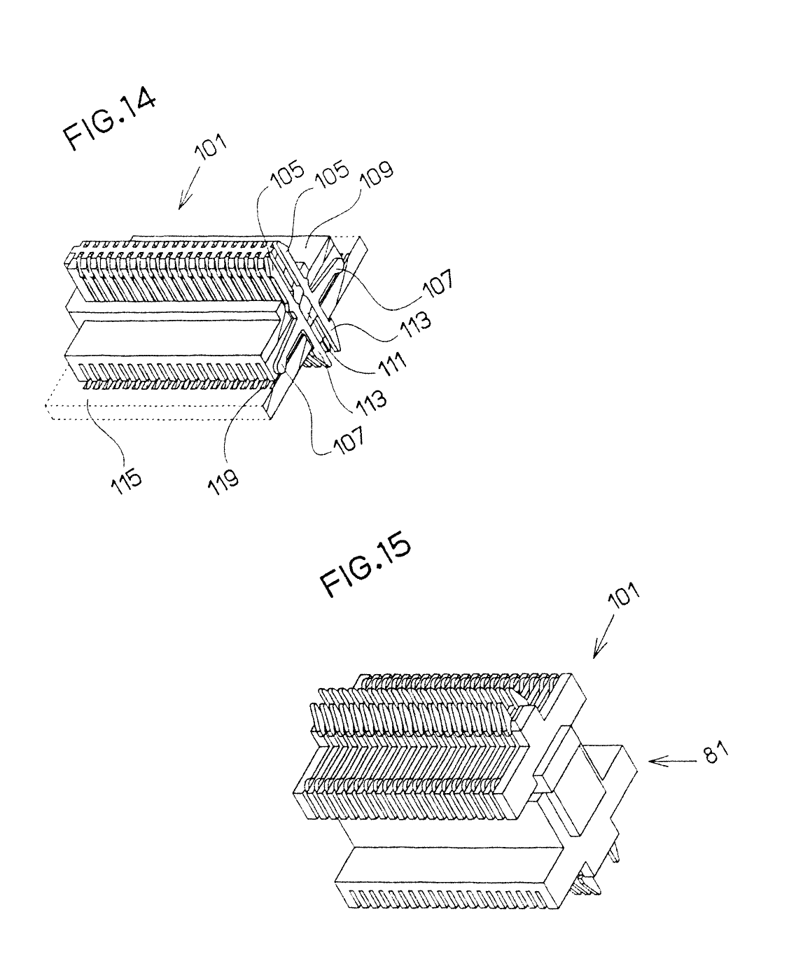

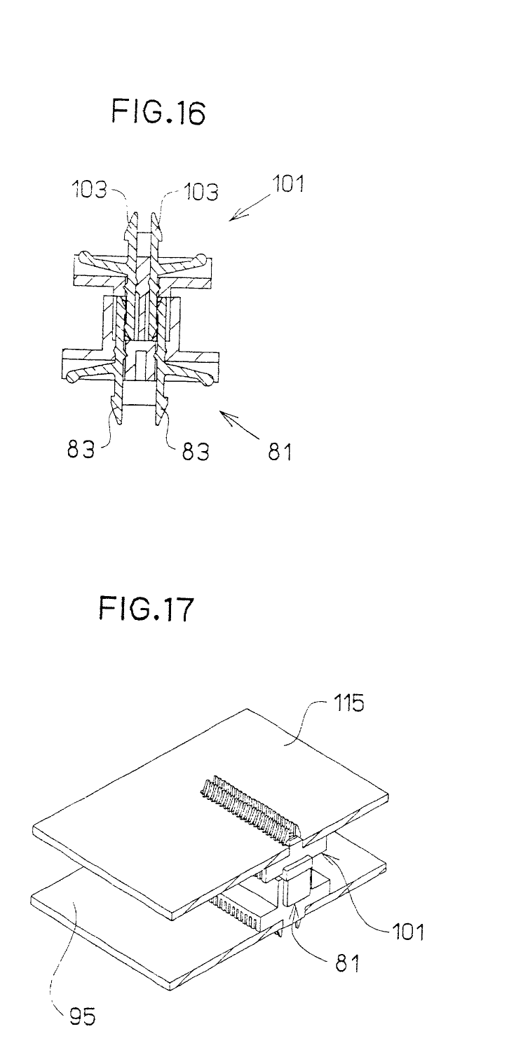

As shown in FIGS. 15 and 16, by inserting the convex portion (wall 111) of male-type connector 101 into the space of female-type connector 81 shown in FIGS. 11 and 12, male-type connector 101 can be engaged with female-type connector 81. When so engaged, referring to FIG. 16, the respective paired terminals (103, 103), (103, 103), . . . of male-type connector 101 come in contact with paired terminals (83, 83), (83, 83), . . . of female-type connector 81, electrically connecting male-type connector 101 and female-type connector 81. Moreover, referring to FIG. 17, this being the case, if male-type connector 101 is mounted to board 115, and female-type connector 81 is mounted to board 95, it is possible to stack and electrically connect board 115 and board 95.

In addition, female-type connector 81 and male-type connector 101 may be used not only for stacking of boards 95 and 115, but each may be also be used separately as a connector for connection of electrical and electronic equipment.

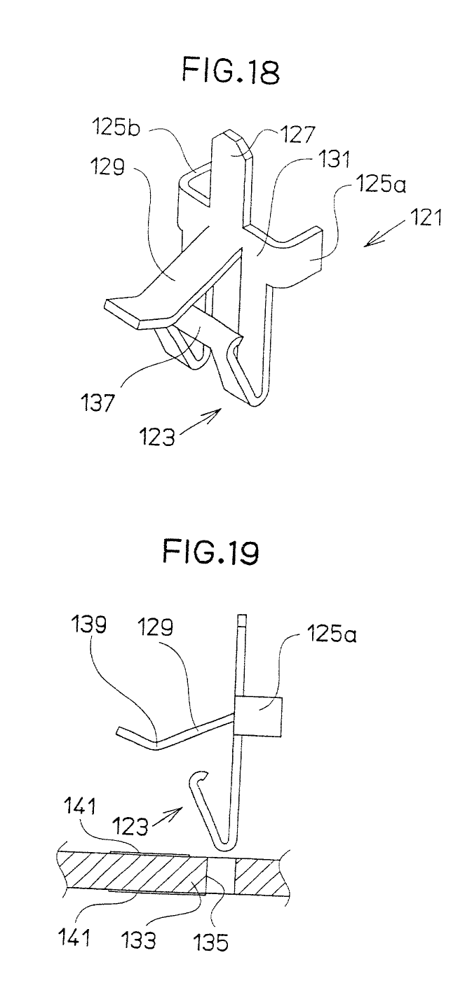

FIG. 18 is an oblique view of a terminal associated with a second embodiment of the present invention, and FIGS. 19 through electrical connector 21 are side views showing changes in the shape of the terminal associated with the present embodiment during mounting of that terminal on a board.

Referring first to FIG. 18, a terminal 121 associated with the present embodiment has a leg 123; two arms 125a, 125b; a neck 127 extending upwardly from a terminal body, described below; a tail 129; and a terminal body 131 which joins these elements together.

Referring to FIGS. 18 and 19, leg 123 is for insertion into a terminal insertion hole 135 on board 133 when terminal 121 is mounted on a board 133. Leg 123 is formed from a strip-like member extending downwardly from terminal body 131 which is bent through a comparatively large angle such that it is somewhat short of being folded back completely upon itself (i.e., so as to, for example, result in an angle of less than 90° with respect to the vertical). As a result, leg 123 (the lower strip-like portion of terminal 121) is wedge-shaped, permitting leg 123 to be inserted into terminal insertion hole 135, and the width of leg 123 at the widest point of the wedge created by folding (i.e., the width in the horizontal direction in FIG. 19 at the widest point of that wedge) is greater than the width of terminal insertion hole 135. Leg 123 displays elasticity (exerts a restorative spring force) with respect to application of a force from the front or rear (from the left or right in FIG. 19), leg 123 being opened to the rear (to the left in FIG. 19) when in the relaxed (unsprung) state. Application of a frontward-directed force (i.e., a force directed to the right in FIG. 19) to this leg 123 will cause the end 137 of leg 123 to move to the front (to the right in FIG. 19), closing the wedge of leg 123, and removal of such force will cause the end 137 of leg 123 to move to the rear (to the left in FIG. 19), opening the wedge of leg 123, by virtue of the aforementioned elasticity. End 137 of leg 123 is rounded so as to allow satisfactory sliding along the bottom surface of board 133 during mounting of terminal 121 on board 133 or during removal of the mounted terminal 121 from board 133. End 137 catches on the rim of terminal insertion hole 135 of board 133 when terminal 121 is mounted on board 133.

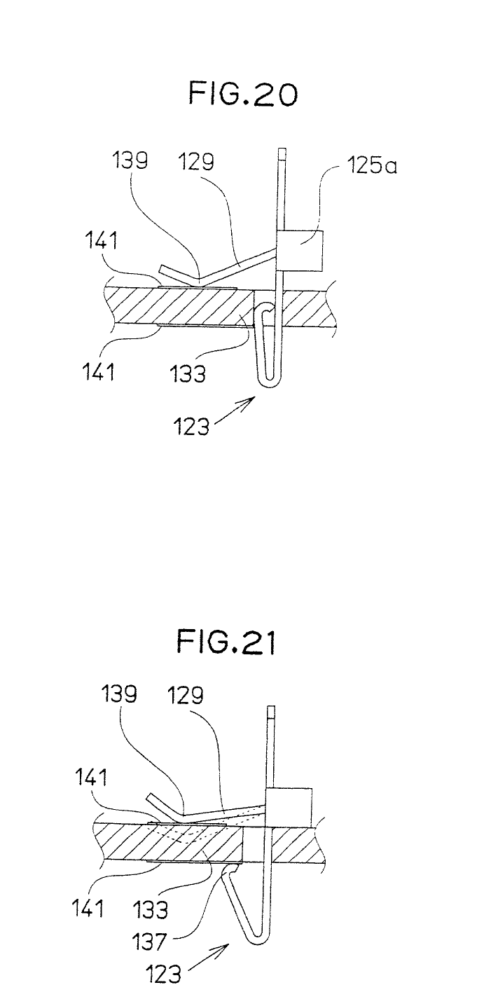

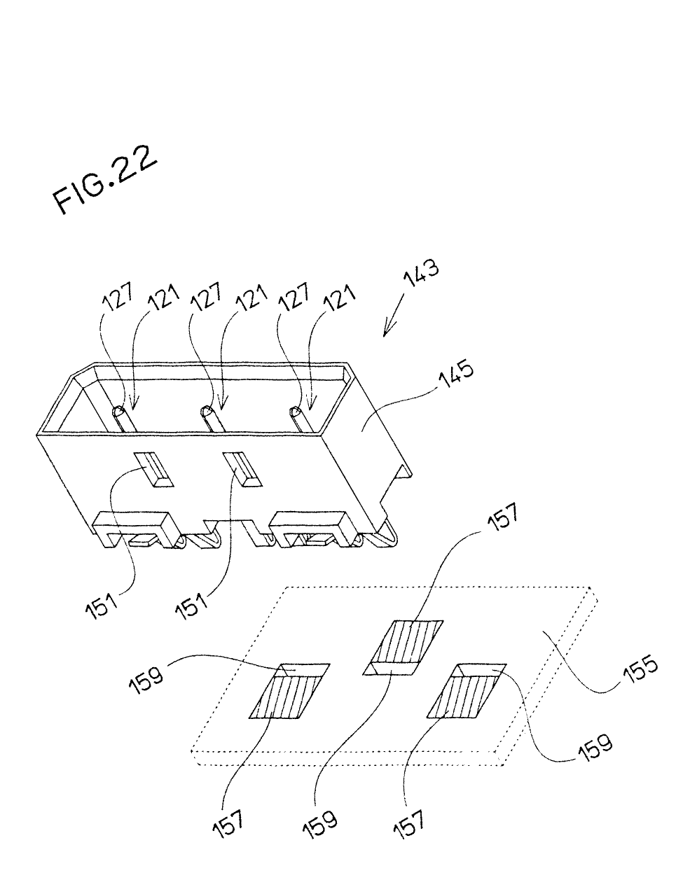

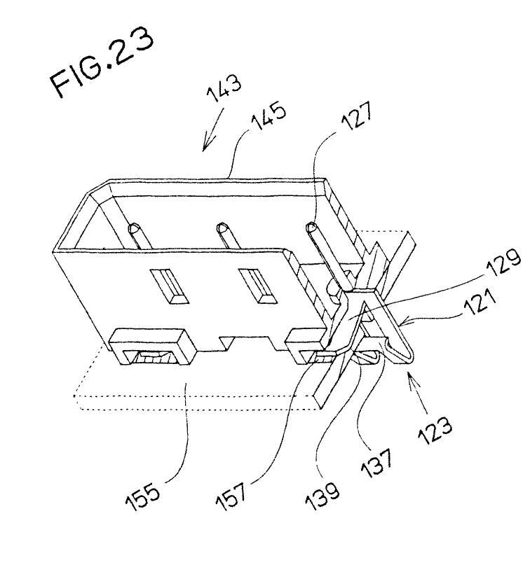

Referring to FIG. 20, upon insertion of leg 123 into terminal insertion hole 135 of board 133, because the width of insertion hole 135 is smaller than the width of the wedge of leg 123, end 137 of leg 123 moves to the front (to the right in FIG. 20), closing the wedge of leg 123, within insertion hole 135. Furthermore, referring now to FIG. 21, upon passage of the closed leg 123 through insertion hole 135 (i.e., upon complete insertion of terminal 121 therein), elasticity of leg 123 causes end 137 of leg 123 to move to the rear (to the left in FIG. 21), opening the wedge of leg 123, and end 137 catches on the rim of insertion hole 135, preventing detachment of terminal 121. Moreover, as shown in the drawings, wiring lands 141 may be provided not just on the top surface of board 133 but on the bottom surface thereof as well (for example, at the rim of insertion hole 135). In such a case, upon complete insertion of terminal 121 in board 133, arms 125a, 125b, described below, are made to come in contact with wiring land(s) 141 on the top surface of board 133, and leg 123 is made to come in contact with a wiring land 141 on the bottom surface of board 133. This permits more stable electrical contact. Furthermore, mutual interconnection of the top and bottom of board 133 by way of terminal 121 is possible, permitting formation of more complex circuitry on board 133 by allowing the circuitry on the top and bottom surfaces thereof to be treated as a single circuit, and the same is true of electrical connectors, stacked-board connectors, male-type connectors, and female-type connectors which are equipped with this terminal 121 associated with the second embodiment of the present invention or with a terminal associated with a variation on the second embodiment of the present invention, described below.

In addition, following complete insertion of leg 123 (i.e., after terminal 121 has been mounted on board 133), by squeezing the wedge of leg 123 and causing it to close to a width that is on the order of or smaller than the width of insertion hole 135, it is possible to cause end 137 of leg 123 to no longer catch on the rim of insertion hole 135 as was described above, making it possible to remove terminal 121 from board 133. That is, terminal 121 associated with the present embodiment is capable of being easily removed from board 133 without causing damage to board 133, terminal 121, or to circuit components of which terminal 121 is a part.

Referring to FIG. 18, the two arms 125a, 125b extend from terminal body 131 toward the front thereof. Upon complete insertion of terminal 121 into board 133, arms 125a, 125b come in contact with the top surface of board 133.

Referring now to FIG. 19, tail 129 extends from terminal body 131 in strip-like fashion so as to be angled downward and to the rear, and is bent upward through a comparatively small angle at a prescribed location. When terminal 121 is inserted in board 133, bend 139 of tail 129 comes in contact with wiring land 141 on the top surface of board 133, and bend 139 is fashioned so as to satisfactorily slide along the top surface of board 133 (over wiring land 141) when terminal 121 is completely inserted in board 133. Tail 129 possesses elasticity (i.e., it exerts a restorative spring force) in the vertical direction.

Referring to FIG. 20, upon insertion of terminal 121 into insertion hole 135 of board 133, tail 129 comes in contact with wiring land 141 on the top surface of board 133. In addition, referring now to FIG. 21, upon complete insertion of terminal 121, tail 129 is bent and raised from the relaxed (unsprung) position indicated by a broken line in the drawing to the sprung position indicated by a solid line in the drawing, bend 139 sliding over wiring land 141. At this time, the aforementioned elasticity of tail 129 causes terminal 121 to rise as if to exit therefrom, but end 137 of leg 123 catches on the rim of insertion hole 135, thus preventing terminal 121 from rising further and becoming detached from board 133. In other words, tail 129, by virtue of an elastic force therefrom, causes end 137 of leg 123 to press against board 133, securing terminal 121 tightly to board 133. This structure permits terminal 121 to be tightly secured to board 133 without use of soldering.

The foregoing construction of terminal 121 allows it to be mounted to and removed from board 133 much more easily and in a much shorter time than was the case conventionally (i.e., inasmuch as it is designed to be removable). Such a terminal 121 may be applied to use in printed circuit boards present in comparatively small-size electrical and electronic equipment such as mobile telephones and portable organizer-type devices which may have voice and data capabilities and be capable of connection with various types of networks, not to mention use in printed circuit boards present in comparatively large-size electrical and electronic equipment such as facsimile devices and personal computers. Specifically, terminal 121 may for example be applied to use in any number of the various types of connectors found on printed circuit boards.

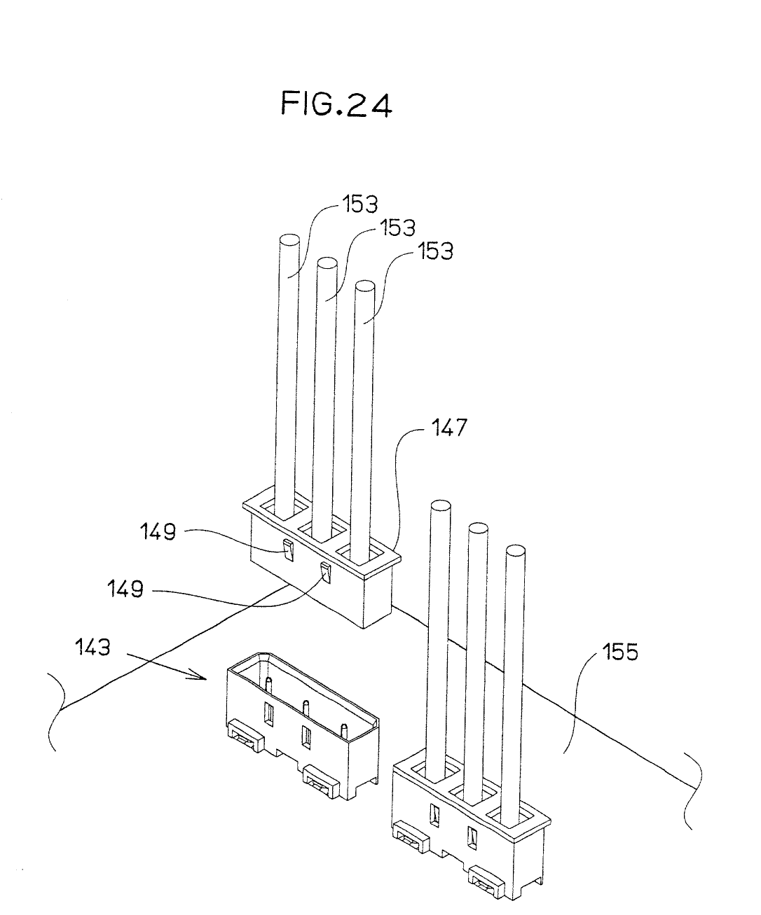

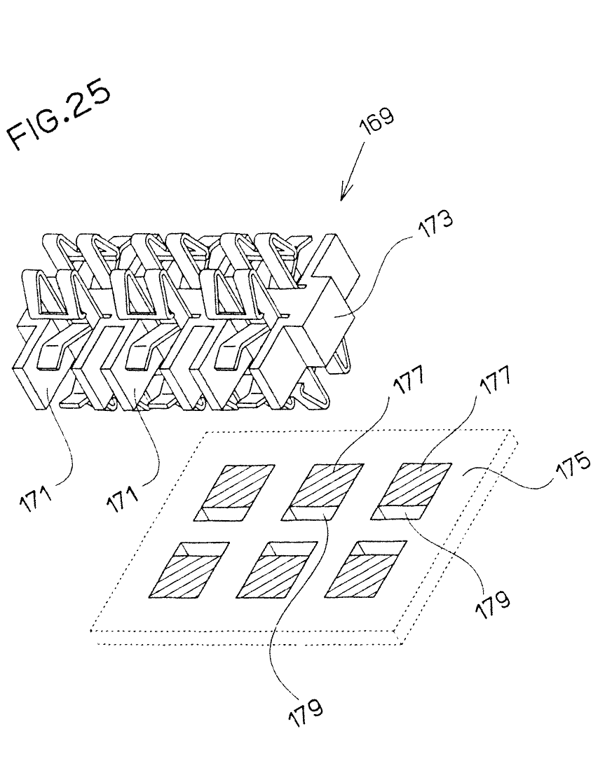

FIG. 22 is an oblique view of an electrical connector wherein use of terminal 121 has been applied. FIG. 23 is an oblique view including a broken-out vertical section and showing the situation existing when the electrical connector of FIG. 22 has been mounted on a board. FIG. 24 is an oblique view showing the situation existing when a mating connector is mated with the electrical connector of FIG. 22.

Referring first to FIG. 22, electrical connector 143 has one or more (for example, three) terminals 121, 121, . . . within a housing 145. Housing 145 is formed such that on a prescribed side thereof there are slots 151, 151 for engagement with tabs 149, 149 of mating connector 147 shown in FIG. 24, respective terminals 121, 121, . . . being disposed in fixed-pitch fashion at the interior thereof. Referring now to FIG. 23, extending upwardly from the basal interior surface of housing 145 are necks 127, 127, . . . of respective terminals 121, 121, . . . ; projecting downwardly from the basal exterior surface of housing 145 are legs 123, 123, . . . (only one such element being shown in the drawing) of respective terminals 121, 121, . . . ; and bends 139, 139, . . . (only one such element being shown in the drawing) of respective tails 129, 129, . . . extend downwardly therefrom. When mating connector 147 shown in FIG. 24 is inserted in this electrical connector 143, necks 127, 127, . . . of respective terminals 121, 121, . . . serve as electric lead connecting members for electrical connection to electric leads 153, 153, . . . of mating connector 147.

Returning to FIG. 22, when this electrical connector 143 is installed on a board 155, legs 123, 123, . . . of respective terminals 121, 121, . . . are inserted within prescribed insertion holes 159, 159, . . . in board 155. As a result, while not shown in the drawing, the wedges of legs 123, 123, . . . of respective terminals 121, 121, . . . are closed and legs 123, 123, . . . enter terminal insertion holes 159, 159, . . . , and bends 139, 139, . . . of respective tails 129, 129, . . . come in contact with wiring lands 157, 157, . . . In addition, referring now to FIG. 23, upon complete insertion of electrical connector 143 into board 155, the closed wedges of respective legs 123, 123, . . . open due to elastic forces therefrom, and the ends 137, 137, . . . (only one such element being shown in the drawing) of legs 123, 123, . . . catch on the rims of insertion holes 159, 159, . . . Furthermore, the positions of respective tails 129, 129, . . . are bent upward from their relaxed (unsprung) positions, the bends 139, 139, . . . of respective tails 129, 129, . . . sliding over wiring lands 157, 157, . . . At this time, tails 129, 129, . . . , by virtue of elastic forces therefrom, cause the ends 137, 137, . . . of legs 123, 123, . . . to press against board 155, securing electrical connector 143 tightly to board 155. This permits electrical connector 143 to be tightly secured to board 155 without use of soldering. Moreover, following complete insertion of electrical connector 143, by squeezing the wedges of respective legs 123, 123, . . . and causing them to close such that they are more or less smaller than the widths of insertion holes 159, 159, . . . , it is possible to cause the ends 137, 137, . . . of legs 123, 123, . . . to no longer catch on the rims of insertion holes 159, 159, . . . as was described above, making it possible to remove electrical connector 143 from board 155. That is, electrical connector 143 associated with the present embodiment is capable of being easily removed from board 155 without causing damage to board 155 or electrical connector 143. Moreover, such an electrical connector 143 is capable of being mounted to and removed from board 155 much more easily and in a much shorter time than was the case conventionally (i.e., inasmuch as it is designed to be removable).

Referring to FIG. 24, a mating connector 147 such as that shown in the drawing may be mated with this electrical connector 143, the action of electrical connector 143 and mating connector 147 when mated being similar to that described in connection with the first embodiment of the present invention with reference to FIG. 7.

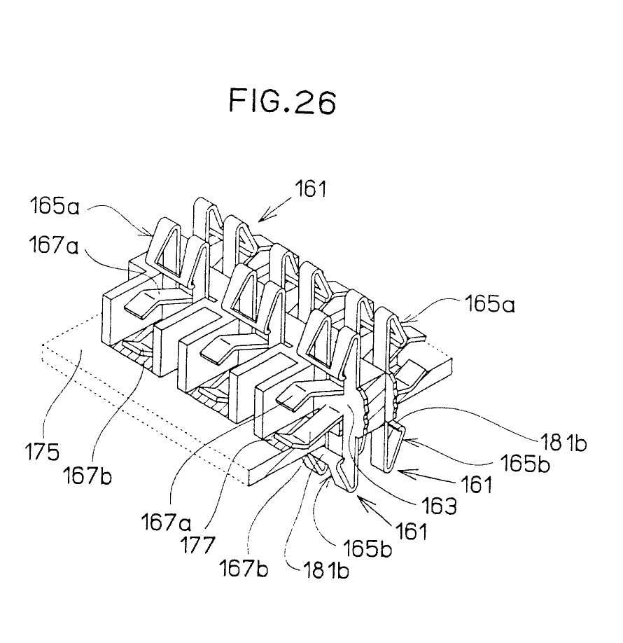

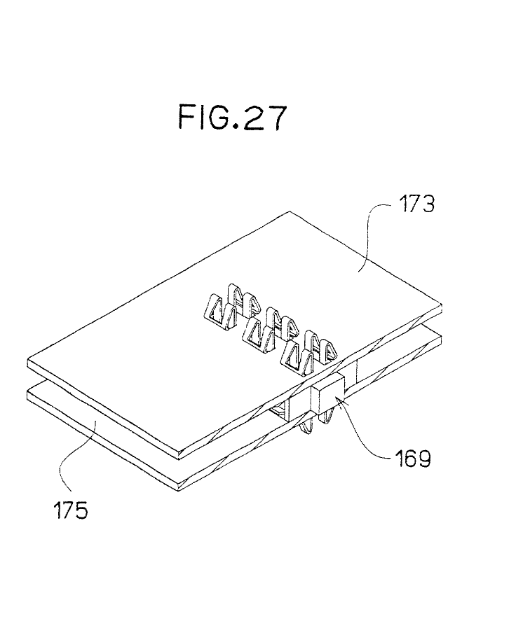

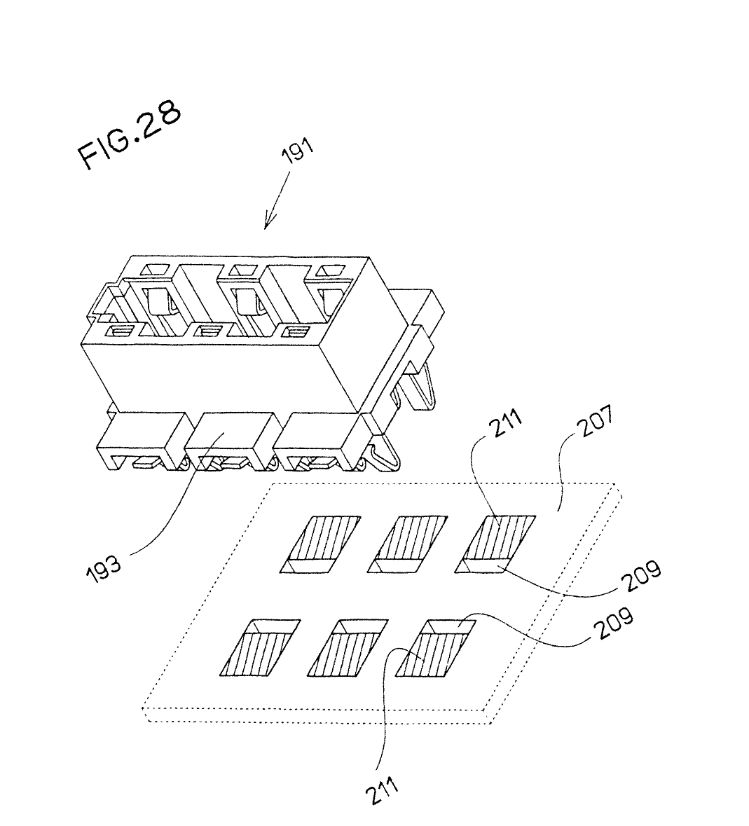

FIG. 25 is an oblique view of a stacked-board connector wherein use of a terminal associated with a first variation on the second embodiment of the present invention has been applied. FIG. 26 is an oblique view including a broken-out vertical section and showing the situation existing when the stacked-board connector of FIG. 25 has been mounted on a board. FIG. 27 is an oblique view showing the situation existing when boards are stacked using the stacked-board connector of FIG. 25.

Referring first to FIG. 26, a terminal 161 associated with a first variation on the second embodiment of the present invention has a vertically symmetric shape and a more or less centrally located body 163. Body 163 has a leg 165a extending upwardly therefrom, and a leg 165b extending downwardly therefrom. Furthermore, body 163 has a tail 167a extending to the rear so as to be angled somewhat upward, and a tail 167b extending to the rear so as to be angled somewhat downward. The structures and functions of respective legs 165a, 165b and respective tails 167a, 167b are similar to those of leg 123 and tail 129 of terminal 121, described above.

Referring to FIGS. 25 and 26, stacked-board connector 169 has a housing 173 possessing spaces 171, 171 for installation of, for example, six terminals. Each terminal installation space 171 has a groove at a prescribed location, a terminal 161 being secured therein by insertion of wing-like flanges extending from either side of body 163 of terminal 161 into this groove. Respective terminals 161, 161, . . . are secured in housing 173 such that their front sides face the interior of housing 173 and their back sides (the side from which tails 167a, 167b extend) face the exterior of housing 173. Referring briefly to FIG. 27, lower legs 165b, 165b, . . . of respective terminals 161, 161, . . . are disposed such that they will protrude from the surface of contact between housing 173 and a board 175, and upper legs 165a, 165a, . . . of respective terminals 161, 161, . . . are disposed such that they will protrude from the surface of contact between housing 173 and a board 173. Furthermore, referring to FIGS. 26 and 27, the bends (reference numerals not shown) of lower tails 167b, 167b, . . . of respective terminals 161, 161, . . . are such that when in their relaxed (unsprung) state, before mounting of stacked-board connector 169 on board 175, they extend beyond the plane corresponding to the surface of contact between housing 173 and board 175 so as to allow them to come in contact with wiring lands 177, 177, . . . on board 175, and the bends (reference numerals not shown) of upper tails 167a, 167a, . . . of respective terminals 161, 161, . . . are such that when in their relaxed (unsprung) state, before mounting of stacked-board connector 169 on board 173, they extend beyond the plane corresponding to the surface of contact between housing 173 and board 173 so as to allow them to come in contact with wiring lands (not shown) on board 173.

With reference now to FIGS. 25 and 26, when a board 175 is mounted on this stacked-board connector 169, the lower legs 165b, 165b, of respective terminals 161, 161, . . . are inserted into prescribed insertion holes 179, 179, . . . on board 175. Upon so doing, the wedges of lower legs 165b, 165b, . . . are closed and enter insertion holes 179, 179, . . . , and the bends of lower tails 167b, 167b, . . . come in contact with wiring lands 177, 177, . . . on board 175. When stacked-board connector 169 is completely inserted into board 175, the closed wedges of lower legs 165b, 165b, . . . open due to elastic forces therefrom, and ends 181b, 181b, . . . catch on the rims of insertion holes 179, 179, . . . Furthermore, lower tails 167b, 167b, . . . of respective terminals 161, 161, . . . being bent upward, respective elastic forces therefrom act so as to cause the ends 181b, 181b, . . . of lower legs 165b, 165b, . . . to press against board 175, securing stacked-board connector 169 tightly to board 175. Referring to FIG. 27, the upper legs 165a, 165a, . . . of respective terminals 161, 161, . . . of stacked-board connector 169 are inserted in like fashion into prescribed insertion holes (not shown) on board 173, mounting stacked-board connector 169 onto board 173. By so doing, it is possible, through use of stacked-board connector 169, for two boards 173, 175 to be stacked in multiple layers, as shown in FIG. 27, and for those boards 173, 175 to be electrically connected.

Moreover, by thereafter squeezing the wedges of respective lower legs 165b, 165b, . . . (or respective upper legs 165a, 165a, . . . ) and causing them to close, it is possible to cause the ends 181b, 181b, . . . of respective lower legs 165b, 165b, . . . (or the ends of respective upper legs 165a, 165a, . . . ) to no longer catch on the rims of the insertion holes as was described above, making it possible to remove stacked-board connector 169 from board 175 (or board 173). That is, stacked-board connector 169 is capable of being mounted to and removed from board 175 (or board 173) easily and in a short time (i.e., inasmuch as it is designed to be removable).

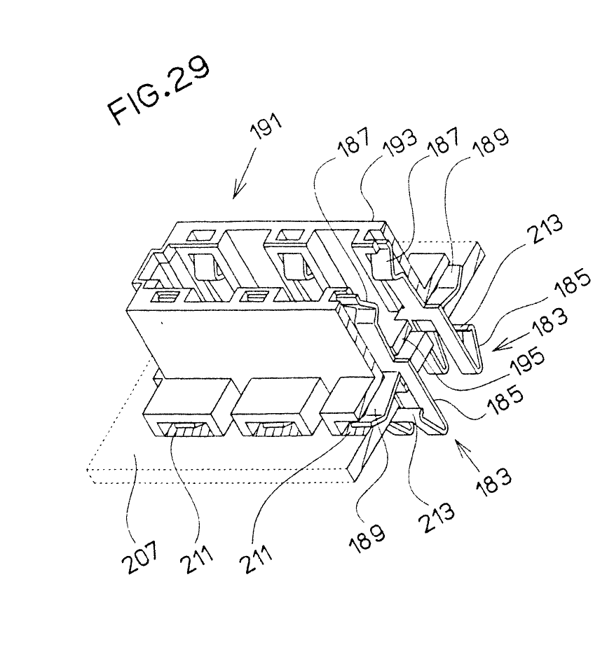

FIG. 28 is an oblique view of a female-type connector wherein use of a terminal associated with a second variation on the second embodiment of the present invention has been applied. FIG. 29 is an oblique view including a broken-out vertical section and showing the situation existing when the female-type connector of FIG. 28 has been mounted on a board.

Referring first to FIG. 29, a terminal 183 associated with a second variation on the second embodiment of the present invention has a leg 185 which extends in a downward direction, a neck 187 extending upwardly from leg 185, and a tail 189 extending from leg 185 at an angle somewhat less than perpendicular with respect thereto. The structures and functions of leg 185 and tail 189 are similar to those of leg 123 and tail 129 of terminal 121, described above. The shape of neck 187 is such as will permit contact with a terminal of a male-type connector, described below, when the male-type connector engages with female-type connector 191.

With continued reference to FIG. 29, female-type connector 191 has a housing 193 possessing space for engagement of a male-type connector, paired terminals 183, 183 being arrayed within housing 193 in fixed-pitch fashion along a direction orthogonal to the vertical section of the drawing. Paired terminals 183, 183 are arranged in horizontally symmetric fashion so as to straddle housing base 195. At paired terminals 183, 183, the tips of necks 187, 187 extend beyond the interior side surface of housing 193, legs 185, 185 protrude from the surface of contact between housing 193 and board 207, and the bends (reference numerals not shown) of tails 189, 189 are such that when in their relaxed (unsprung) state, before mounting of female-type connector 191 on board 207, they extend beyond the plane corresponding to the surface of contact between housing 193 and board 207.

Action of this female-type connector 191 during mounting thereof on board 207 is more or less identical to that of the above-described stacked-board connector 169 during mounting thereof on a board. That is, with reference to FIGS. 28 and 29, upon insertion of the protruding legs 185, 185, . . . of respective terminals 183, 183, . . . into prescribed insertion holes 209, 209, . . . on board 207, the wedges of respective legs 185, 185, . . . are made to close and enter insertion holes 209, 209, . . . , and the bends of tails 189, 189, . . . come in contact with wiring lands 211, 211, . . . When female-type connector 191 is completely inserted into board 207, the closed wedges of respective legs 185, 185, . . . open due to respective elastic forces therefrom, and the ends 213, 213, . . . of legs 185, 185, catch on the rims of insertion holes 209, 209, . . . , as shown in FIG. 29. Furthermore, the tails 189, 189, . . . of respective terminals 183, 183, . . . being bent upward, respective elastic forces therefrom act so as to cause the ends 213, 213, . . . of respective legs 185, 185, . . . to press against board 207, securing female-type connector 191 tightly to board 207. Moreover, by thereafter squeezing the wedges of respective legs 185, 185, . . . and causing them to close, it is possible to cause the ends 213, 213, . . . of respective legs 185, 185, . . . to no longer catch on the rims of insertion holes 209, 209, . . . as was described above, making it possible to remove female-type connector 191 from board 207.

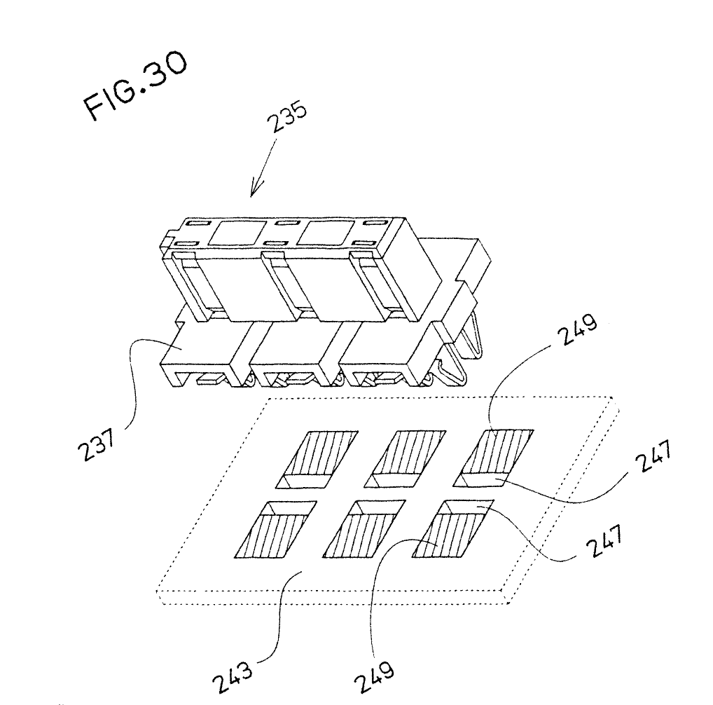

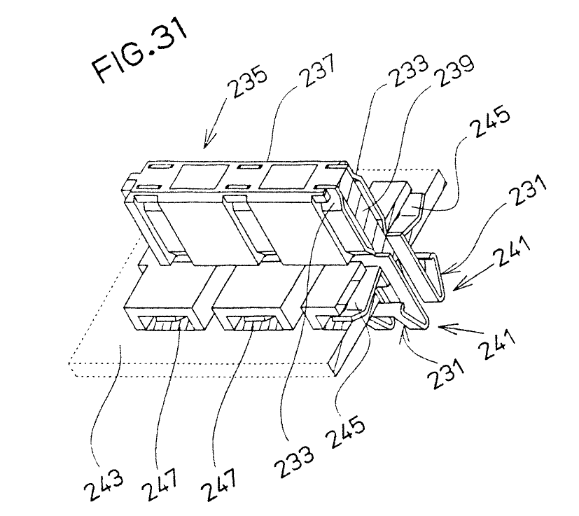

FIG. 30 is an oblique view of a male-type connector wherein use of a terminal associated with a third variation on the second embodiment of the present invention has been applied. FIG. 31 is an oblique view including a broken-out vertical section and showing the situation existing when the male-type connector of FIG. 30 has been mounted on a board.

Referring first to FIG. 31, the shape of a terminal 231 associated with a third variation on the second embodiment of the present invention is more or less identical to that of the above-described terminal 183 of female-type connector 191, the only exception being that the shape of neck 233 is somewhat different. With additional momentary reference to FIG. 29, neck 233 of terminal 231 is such that it comes in contact with neck 187 of terminal 183 of female-type connector 191 when male-type connector 235 engages with female-type connector 191.

Referring again to FIG. 31, male-type connector 235 has a housing 237 possessing a convex cross-section so as to permit engagement with female-type connector 191, paired terminals 231, 231 being arrayed more or less centrally on housing 237 in fixed-pitch fashion along a direction orthogonal to the vertical section of the drawing. Paired terminals 231, 231 are arranged in horizontally symmetric fashion so as to straddle wall 239 which is located more or less centrally on housing 237. The necks 233, 233, . . . of respective terminals 231, 231, . . . are exposed, not being covered by either wall surface of wall 239; the legs 241, 241, . . . thereof protrude from the surface of contact between housing 237 and board 243; and the bends of tails 245, 245, . . . are such that when in their relaxed (unsprung) state, before mounting of male-type connector 235 on board 243, they extend beyond the plane corresponding to the surface of contact between housing 237 and board 243 so as to permit contact with wiring lands 249, 249, of board 243.

Action of this male-type connector 235 during mounting thereof on board 243 is more or less identical to that of the above-described female-type connector 191 during mounting thereof on a board.

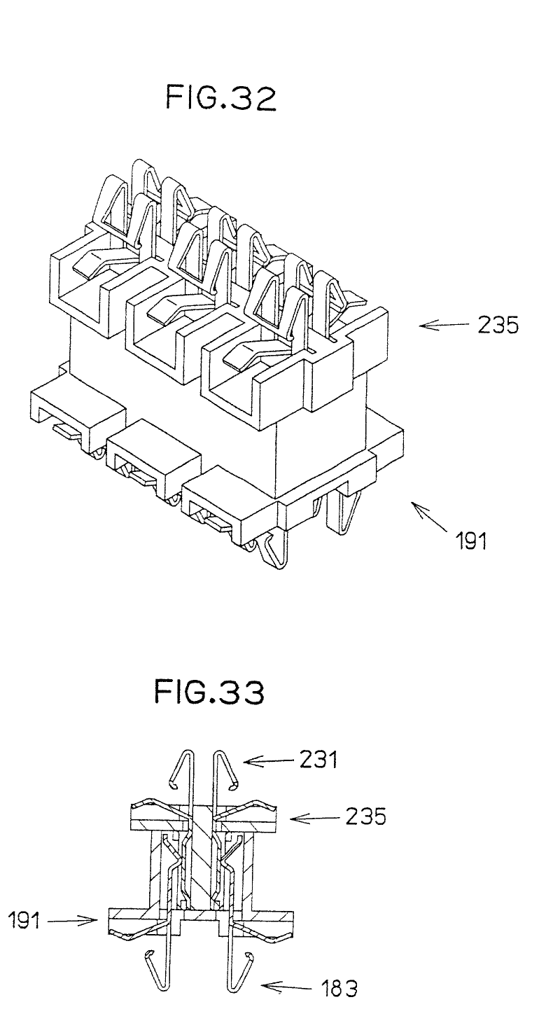

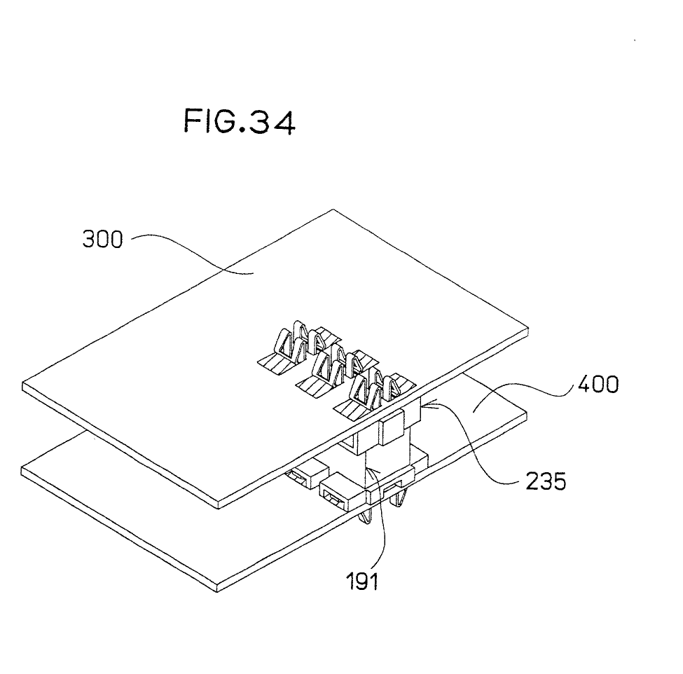

As shown in FIGS. 32 and 33, by inserting the convex portion (wall 239) of male-type connector 235 into the space of female-type connector 191 shown in FIGS. 28 and 29, male-type connector 235 can be engaged with female-type connector 191. When so engaged, referring to FIG. 33, respective terminals 231, 231, . . . of male-type connector 235 come in contact with respective terminals 183, 183, . . . of female-type connector 191, electrically connecting male-type connector 235 and female-type connector 191. Moreover, referring to FIG. 34, this being the case, if male-type connector 235 is mounted to board 300, and female-type connector 191 is mounted to board 400, it is possible to stack and electrically connect board 300 and board 400.

In addition, female-type connector 191 and male-type connector 235 may be used not only for stacking of boards 300 and 400, but each may be also be used separately as a connector for connection of electrical and electronic equipment.

Whereas several preferred embodiments of the present invention and variations thereof have been described above, these examples have been presented merely for purposes of describing the invention and it not intended that the invention should be limited thereby. The present invention may be carried out in the context of a wide variety of modes and embodiments other than those specifically presented herein.

What is claimed is:

1. A terminal comprising:
a) a leg that is inserted into a recess on a substrate;
b) an engagement member provided on the aforesaid leg so as to prevent detachment of the aforesaid leg from the aforesaid recess as a result of engagement of the aforesaid engagement member with the aforesaid recess when the aforesaid leg is inserted into the aforesaid recess; and
c) an electrically conductive region that forms a closed circuit as a result of electrical connection with a wiring pattern on the aforesaid substrate when the aforesaid leg is at a prescribed location within the aforesaid recess.

2. A terminal according to claim 1 further comprising a terminal locking member that causes the aforesaid substrate to come in compressive contact with the aforesaid engagement member, locking the aforesaid terminal to the aforesaid substrate, when the aforesaid engagement member of the aforesaid leg engages with the aforesaid recess.

3. A terminal according to claim 2 wherein the aforesaid terminal locking member accomplishes the aforesaid compressive contact by means of an elastic restoring force acting in a direction opposite to the direction of insertion of the aforesaid leg.

4. A terminal according to claim 1 wherein the aforesaid recess is a through-hole.

5. A terminal according to claim 1 wherein there are a plurality of the aforesaid legs, said plurality of legs branching off from the body of the aforesaid terminal and being constructed so as to permit elastic deformation such that an elastic restoring force acts so as to increase the size of a gap between respective legs.

6. A terminal according to claim 1 constructed so as to permit elastic deformation such that an elastic restoring force acts in a direction tending to press the aforesaid leg against a wall surface of the aforesaid recess.

7. A connector equipped with a terminal according to any one of claims 1 through 6, said connector being for electrical connection of a board to another board or to other electric or electronic equipment.
